(19) United States
(12) Patent Application Publication
(10) Pub. No.: US 2006/0270201 A1
(43) Pub. Date: Nov. 30, 2006

(54) Nano-air-bridged lateral overgrowth of GaN semiconductor layer

(76) Inventors: Soo Jin Chua, Singapore (SG); Yadong Wang, Singapore (SG); Keyan Zang, Singapore (SG)

Correspondence Address: ACKERMAN, STEPHEN;George O Saile and Assocs, 28 Davis Ave, Poughkeepsie, NY, 12603, US

(21) Appl. No.: 11/434,399

(22) Filed: May 15, 2006

Related U.S. Application Data
(60) Provisional application No. 60/680,712, filed on May 13, 2005.

(51) Int. Cl. H01L 21/20

(52) U.S. Cl. 438/481

(57) ABSTRACT

A technique for growing a high quality gallium nitride layer on a uniform nano-patterned substrate is described. The invented technique is based on the transfer of ordered nano-patterns from a nano-template to the substrate, followed by the growth of gallium nitride on the nano-patterned substrate. The nano-patterned substrate serves as a buffer layer to reduce the stress and dislocations.

This application claims benefit of U.S. Provisional Patent Application Ser. No. 60/680,712, filed on May 13, 2005.

### FIELD OF THE INVENTION

This invention relates to optoelectronics devices and fabrication method, and more particularly to Group III-Nitride semiconductor structures.

### BACKGROUND OF THE INVENTION

Gallium nitride (GaN) has been shown to be a useful material for devices such as light-emitting diodes, laser diodes and high power transistor devices. As used herein, “gallium nitride” or “GaN” refers to gallium nitride and Group III-nitride alloys thereof, including aluminum gallium nitride (AlGaN), indium gallium nitride (InGaN) and aluminum indium gallium nitride (AlInGaN), and other Group-III nitrides and alloys thereof such as indium nitride (InN) and aluminum nitride (AlN).

GaN is usually fabricated as a heteroepitaxial layer on foreign substrates due to the fact that high-quality bulk crystals of GaN are currently unavailable for commercial use. Such heteroepitaxial growth typically gives rise to high dislocation density and residual strain inside the layers resulting from both lattice mismatch and differences in thermal expansion coefficients. Presence of high defect density and residual strain in GaN materials leads to poor electrical and optical properties of devices.

Selective growth and then lateral overgrowth on a patterned substrate has been shown to be a typical growth technology to improve the film quality. Epitaxial lateral overgrowth (ELO) and growth on the porous substrates are two techniques that can reduce the dislocation density and residual strain in the GaN film. ELO technique consists of masking an underlying layer of GaN with a mask having a pattern of openings and growing the GaN through the openings and then laterally over the mask. It was found that the portion of the GaN layer grown laterally over the mask exhibits a much lower dislocation density than the underlying GaN layer. Nevertheless, there are still many technological and fundamental problems associated with this approach such as strain-driven tilting of the c-axis occurring in the overgrowth region (wing-tilt) and impurity incorporation (probably Si or O from the mask material SiO₂). Also reduction of dislocation obtained in this process is limited to primarily above the masked region. Another technique to improve the film quality is GaN overgrowth on the nano-porous substrate, such as porous silicon carbide (SiC) and porous GaN. These porous templates are usually formed by anodization in hydrofluoric acid under UV illumination. With such a preparation method, the pore diameter, interpore distance and uniformity are difficult to control.

Additional techniques for forming the uniform nanoporous substrate include selectively etching the substrate with a material of interest through the nano-channel of a template. Examples of such templates include anodic aluminum oxide and meso-porous materials, which may be provided with arrays of pores therein. The pore diameter and pore packing density of an anodic aluminum oxide layer can be controlled by anodizing an aluminum layer with an electrolyte to provide an anodic aluminum oxide layer having nano-pores therein.

### SUMMARY OF THE INVENTION

It is therefore an object of the present invention to provide an improved method of fabricating a gallium nitride semiconductor epilayer.

It is also an object of the invention to provide improved gallium nitride layers.

In accordance with the above objectives, the present invention discloses a technique for growing a high quality gallium nitride layer on a uniform nano-patterned substrate. The invented technique is based on the transfer of ordered nano-patterns from a nano-template to the substrate, followed by the growth of gallium nitride on the nano-patterned substrate. The nano-patterned substrate serves as a buffer layer to reduce the stress and dislocations.

According to the present invention, a step is performed to pattern an underlying gallium nitride layer on a sapphire substrate with a mask template that includes an array of nano-channels therein and through which the underlying gallium nitride layer is etched to form the nano-pores in the gallium nitride surface and nano-posts therebetween. This etching template may comprise any non-lithography self-assembly nano-template or artificial patterning defined by high-resolution lithography. This selective etching preferably uses the etching template as an etching mask to transfer the nano-channel in the template to the underlying layer on a substrate.

According to the present invention, the step of forming an etching template may include forming a metal film such as an aluminum film on the underlying gallium nitride surface and then repeatedly anodizing the metal film to convert it into an anodic metal oxide layer having nano-channels therein. The etching step may include wet etching by using chemical solvents and dry etching by using ion reaction.

According to the present invention, the step of material growth may include many growth techniques and many kinds of growth reactors that can be used for nitride growth.

According to the present invention, growth proceeds on the nano-post of the underlying gallium nitride, then air-bridging the pores through lateral overgrowth to form a continuous smooth layer. These air bridges formed by the lateral overgrown gallium nitride layer over the nano-pores in the gallium nitride layer may be beneficial for strain relaxation and dislocation reduction in the overgrown layer. Microelectronic devices or optoelectronic devices may be formed in the gallium nitride overgrown layer.

The invention has numerous advantages, a few which are described, hereafter, as merely examples:

1. An advantage of the invention is that it reduces dislocation density and stress in the epitaxial layer grown over a substrate.

2. Another advantage of the invention is that the radiative recombination efficiency in the epitaxial layer is improved.

3. Another advantage of the invention is that contamination arising from the use of a mask (silicon dioxide or silicon nitride) can be eliminated.

4. Another advantage of the invention is that it is simple in design and easily implemented on a mass scale for commercial production.

### BRIEF DESCRIPTION OF THE DRAWINGS

In the accompanying drawings forming a material part of this description, there is shown:

FIGS. 1A-1E are cross-sectional views of structures that illustrate the method of forming an anodic aluminum oxide layer in a preferred embodiment of the present invention.

FIG. 2 illustrates the transfer of the nano-pattern to the underlying substrate in accordance with the present invention.

FIG. 3 illustrates the nano-patterned substrate after the original nano-template removal in accordance with the present invention.

FIG. 4 illustrates the overgrowth of semiconductor material on the nano-patterned substrate in accordance with the present invention.

FIGS. 5A and 5B are cross-sectional views illustrating the dislocation density reduction in the overgrowth material in accordance with the present invention.

### DETAILED DESCRIPTION OF THE EMBODIMENTS

The present invention will be described more fully hereinafter with reference to the accompanying drawings, in which the preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention. In the drawings, the thickness of layers and regions are exaggerated for clarity.

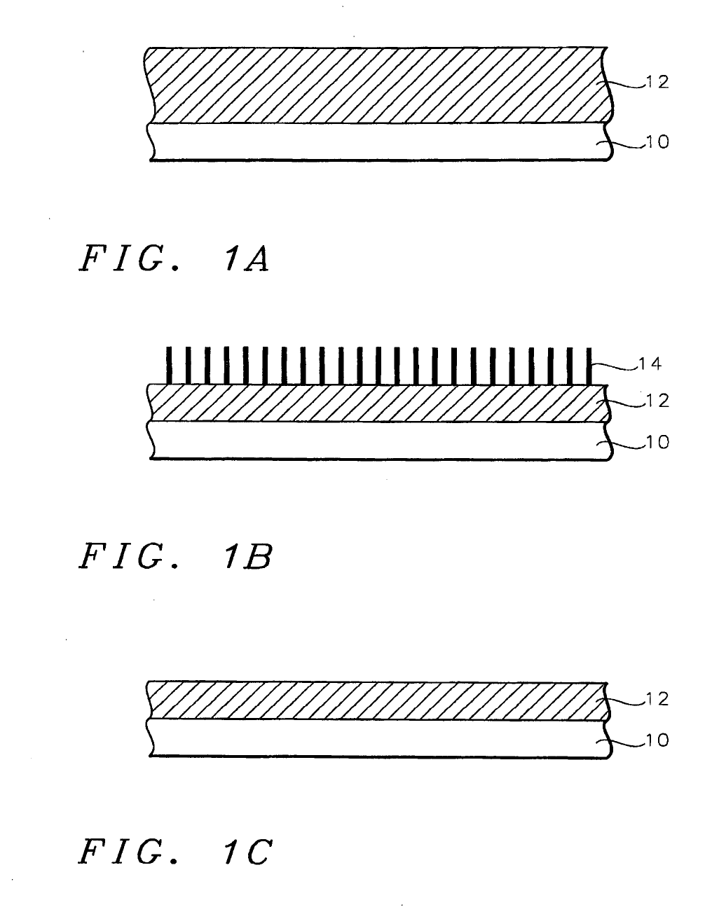

The present invention provides a method to form a high-quality epitaxial layer of gallium nitride or other Group III-nitride materials on a substrate. Referring now to FIG. 1, the method of the present invention will be described. The substrate 10 may be GaN grown on sapphire, Silicon carbide (SiC), Zinc Oxide (ZnO) or other substrate. GaN refers here to gallium nitride and Group III-nitride alloys thereof, including aluminum gallium nitride (AlGaN), indium gallium nitride (InGaN) and aluminum indium gallium nitride (AlInGaN), or other Group-III nitrides and alloys thereof, such as indium nitride (InN), aluminum nitride (AlN), and so on. Reference to gallium nitride hereinafter is to be understood to mean gallium nitride or any other Group-III nitride.

A mask template having nano-patterns therein is formed over the substrate. The mask template includes an array of nano-channels therein and through which the underlying gallium nitride layer is etched to form nano-pores in the gallium nitride surface and nano-posts therebetween. The nano-patterns may comprise any shape with geometrical scale up to hundreds of nanometers. The etching template may comprise any non-lithography self-assembly nano-template or artificial patterning defined by high-resolution lithography. For example, a self-assembled nanoporous anodic aluminum oxide film may be used as the nano-template.

First, aluminum 12 is evaporated on the substrate 10, as illustrated in FIG. 1A. Then, the aluminum is partially anodized 14 depending on the desired final film thickness, as shown in FIG. 1B. The thickness of the layer 14 can be controlled by the initial Al thickness and the first anodized alumina thickness which is dependant on the anodization conditions such as temperature, voltage, and so on. The preferred electrolyte may include sulfuric acid, oxalic acid and phosphoric acid. Referring now to FIG. 1C, the first anodized alumina film 14 is removed using a chemical etch, such as for example, a mixture of H₃PO₄ and H₂CrO₂, leaving a patterned Al film 12 of the desired thickness for the final template. After the first anodization, the remaining film 12 has some trace of the anodization on its surface, which will guide the second anodization. Using the two-step anodization process can improve the order of the nano-pores in the film. Optionally, a one-step anodization process can be used. Preferrably, as shown in FIG. 1D, the remaining Al is anodized a second time 16 to get a more ordered anodized aluminum oxide (AAO) template. The size of the nano-pores and distance between the pores are controlled by the anodization conditions, such as applied voltage, electrolyte concentration, and so on. Lastly, the thin barrier layer 15 at the pore bottom is removed by a short chemical etching, as shown in FIG. 1E. The nano-template 16 has a preferred thickness of between about 200 and 800 nm.

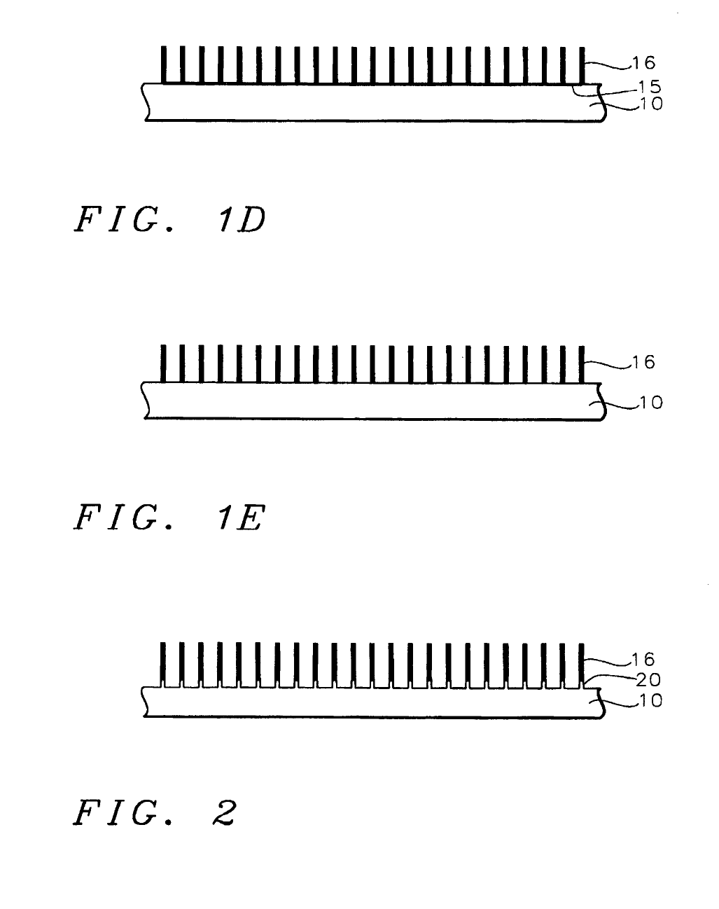

Referring now to FIG. 2, as used herein, the nano-template 16 acts as an etching mask for the transfer of the nano-pattern in the nano-template to the substrate 10. In the present embodiment, inductively coupled plasma (ICP) etching technique is used for the pattern transfer to the substrate, as shown by 20. It should be understood, however, that various etching techniques can be adopted to achieve the pattern transfer, such as wet chemical etching and other dry etching methods.

Now, referring to FIG. 3, after the nano-pattern transfer, the nano-template 16 is removed from the sample structure, such as by a chemical etching. Now the nano-patterned substrate has nano-pores 22 in its surface and nano-posts 24 therebetween.

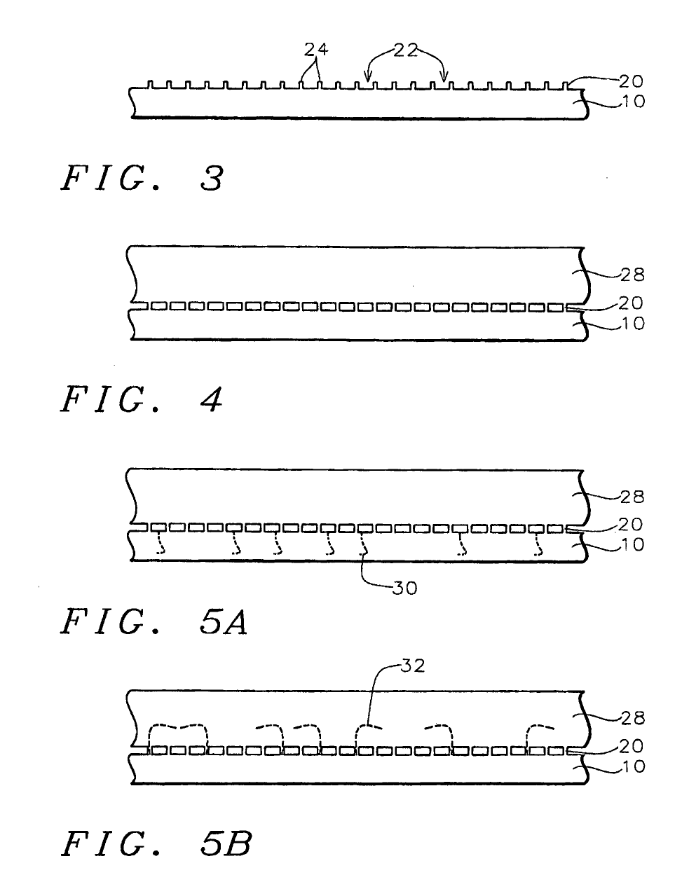

Referring now to FIG. 4, epitaxial growth originates from the nano-posts 24 and then continues in a lateral overgrowth with air-bridging and coalesces to form the continuous layer 28, which will be of much higher quality than the original layer. Growth does not occur within the nano-pores because the large aspect ratio (pore depth divided by the pore diameter) favors such growth behavior. Also, growth parameters such as growth temperature and flow rate can be tuned such that growth does not occur within the nano-pores. The rate of lateral overgrowth is controlled by growth conditions, temperature, pressure, and reactant flow rates. The dislocation density is reduced because some dislocations are blocked by the structure and some are bent in the lateral growth. Also, the stress in the overgrown layer is reduced compared with the underlying layer because some of the stresses are shared by the nano-pores.

FIG. 5 schematically shows that dislocations either terminate at the bottom of the nano-pores 30 (FIG. 5A) or bend to form a dislocation loop 32 (FIG. SB). The material above the bent dislocation loops is essentially dislocation-free. The present invention is an effective and less costly approach than competing approaches to reduce dislocations.

One or more additional layers of GaN or other Group-III nitride material can be formed over the high quality continuous layer 28 and, if present, will be understood to be included in layer 28. Optoelectronic or microelectronic devices can then be formed in the high quality Group-III nitride layer 28.

The process of the invention has been implemented. Scanning electron microscope (SEM) images of the nano-patterned substrate show that the nano-pores are uniform in the whole wafer. Higher magnification transmission electron microscope (TEM) micrographs near the pore regions show that the nano-pore structure in the GaN template significantly affects the structure of the dislocations in the overgrown film. The dislocation density is reduced in the overgrown GaN layer. There are two kinds of dislocation reduction mechanisms in the overgrowth GaN films. Since overgrowth takes place at the small area between the pores, some threading dislocations originating from the underlying pore regions are blocked from propagating into the overgrowth layer. This is very similar to the SiO₂ (or SiN) mask effect in which some thread dislocations are blocked by these mask materials. So the pores in the present invention function as a “reverse mask”. In conventional ELO growth, GaN selectively grows inside the window between mask materials. In the invention, GaN selectively grows in the small area between the pores (reverse mask). In addition, the bending of the threading dislocations also happens during the lateral overgrowth. This bending of dislocations increases their chances of combining and annihilating with each other, which would lead to the reduction of the dislocation density in the overgrown layer as well.

### EXAMPLE

The following Example is given to show the important features of the invention and to aid in the understanding thereof. Variations may be made by one skilled in the art without departing form the spirit and scope of the invention.

In an effort to illustrate the quality of the overgrown sample, a controlled sample was also loaded into the chamber for growth under the same conditions, but without any nano-pattern on the surface. Atomic force microscope (AFM) images for the overgrown sample and control sample were obtained. The overgrown sample shows a surface that is much smoother than the control sample. Also the pit density is largely reduced in the overgrown sample. The surface root mean square (RMS) roughness is 0.25 nm and 0.39 nm for the overgrown sample and the controlled sample, respectively.

A crystallographic analysis by high-resolution x-ray diffraction rocking curves (omega scans) for both samples were obtained. X-ray diffraction is indicative of structures such as dislocations. The full width at half maximum (FWHM) of x-ray rocking curves has been used to quantify crystalline imperfection. FWHM values of (0002) symmetry and (101_2) asymmetry planes are decreased for the overgrown GaN sample compared with the control sample. The reduced FWHM shows clearly that both pure edge and pure screw and/or mixed threading dislocations are reduced in the nano-overgrown GaN film.

The optical qualities of the samples were investigated by micro-photoluminescence and micro-Raman spectra. The nano-air-bridge overgrown sample showed not only enhanced luminescence but also a red shift compared with the control sample, which is due to the strain relaxation in the overgrown sample. This strain relaxation is confirmed by micro-Raman spectra. The E₂(TO) mode in the micro-Raman spectra is sensitive to the amount of strain in the film. A red shift of the E₂(TO) of the overgrown sample indicates strain relaxation in the nano-air-bridge overgrown sample compared with the control sample.

In summary, the process of the present invention provides a method of fabricating an essentially dislocation-free GaN layer on a substrate. The essentially dislocation-free GaN layer is formed over a nano-porous GaN layer on a substrate.

What is claimed is:

1. A method of growing a high-quality Group-III nitride layer on a substrate comprising the following steps:
(i) depositing a Group-III nitride layer on said substrate;
(ii) forming a nano-template having an array of defined nano-channels extending through to underlying said Group-III nitride layer;
(iii) etching underlying said Group-III nitride layer and forming nano-pores in said Group-III nitride layer and nano-posts between said nano-pores, using said nano-template as an etching mask, wherein said nano-posts and nano-pores form a nano-patterned Group-III nitride surface;
(iv) removing said nano-template; and
(v) growing said high-quality Group-III nitride layer on said nano-posts and air-bridging over said nano-pores to achieve lateral coalescence and hence to form a continuous high-quality Group-III nitride layer overlying said nano-posts and said nano-pores.

2. The method according to claim 1 wherein said substrate comprises a material that can be used in Group-III nitride growth.

3. The method according to claim 1 wherein said nano-template comprises any material having nano-patterns in it.

4. The method according to claim 1 wherein forming said nano-template comprises forming a nanoporous anodic aluminum oxide thin film on said Group-III nitride layer on said substrate.

5. The method according to claim 1 wherein forming said nano-template comprises:
forming a metal film on said group-III nitride layer on said substrate; and
anodizing said metal film into an anodic metal oxide layer having said nano-channels therethrough.

6. The method according to claim 1 wherein said etching step comprises: dry etching, wet etching or any other etching process.

7. The method according to claim 1 wherein said nano-patterned Group-III nitride surface has nano-patterns comprising any shape with geometrical scale up to hundreds of nanometers.

8. The method according to claim 1 wherein said growing said high-quality Group-III nitride layer comprises growth on top of said nano-posts and air-bridge-mediated lateral overgrowth.

9. The method according to claim 8 wherein growth is inhibited inside said nano-pores.

10. The method according to claim 8 wherein a rate of said lateral overgrowth is controlled by growth conditions, temperature, pressure, and reactant flow rates.

11. The method according to claim 1 further comprising:
growing a subsequent Group III-nitride epilayer overlying said high-quality Group-III nitride layer.

12. The method according to claim 1 said high quality Group-III nitride layer has increased stress relaxation and reduced dislocation density as compared to first said Group-III nitride layer.

13. A method of growing a high-quality gallium nitride layer on a nano-patterned gallium nitride surface of a substrate comprising the following steps:
(i) depositing a gallium nitride layer on said substrate;
(ii) forming a nano-template having an array of defined nano-channels extending through to underlying said gallium nitride layer;
(iii) etching underlying said gallium nitride layer and forming nano-pores in said gallium nitride layer and nano-posts between said nano-pores, using said nano-template as an etching mask, wherein said nano-posts and nano-pores form said nano-patterned gallium nitride surface;
(iv) removing said nano-template; and
(v) growing said high-quality gallium nitride layer on said nano-posts and air- bridging said nano-pores to achieve lateral coalescence and hence to form a continuous high-quality gallium nitride layer overlying said nano-posts and said nano-pores.

14. The method according to claim 13 wherein said substrate comprises a material that can be used in gallium nitride growth.

15. The method according to claim 13 further comprising a buffer layer between said substrate and said gallium nitride layer.

16. The method according to claim 13 wherein said nano-template comprises any material with nano-patterns in it.

17. The method according to claim 13 wherein forming said nano-template comprises forming a nanoporous anodic aluminum oxide thin film on said gallium nitride layer on said substrate.

18. The method according to claim 17 wherein forming said nano-template further comprises:
forming a metal film on said gallium nitride layer on said substrate; and
anodizing said metal film into an anodic metal oxide layer.

19. The method according to claim 13 wherein said etching step comprises: dry etching, wet etching or any other etching process.

20. The method according to claim 13 wherein said nano-patterned gallium nitride surface has nano-patterns comprising any shape with geometrical scale up to hundreds of nanometers.

21. The method according to claim 13 wherein said growing said high-quality gallium nitride layer comprises growth on top of said nano-posts and air-bridge-mediated lateral overgrowth.

22. The method according to claim 21 wherein growth is inhibited inside said nano-pores.

23. The method according to claim 21 wherein a rate of said lateral overgrowth is controlled by growth conditions, temperature, pressure, and reactant flow rates.

24. The method according to claim 13 further comprising:
growing an additional gallium nitride layer on top of said high-quality gallium nitride layer.

25. The method according to claim 13 further comprising:
growing a subsequent Group III-nitride epilayer overlying said high-quality gallium nitride layer.

26. A high-quality Group-III nitride layer on a substrate comprising:
a Group-III nitride layer on said substrate;
a nano-pattern of nano-pores in said Group-III nitride layer having nano-posts therebetween; and
said high-quality Group-III nitride layer overlying said nano-posts and said nano- pores.
